(19) United States
(12) Patent Application Publication
(10) Pub. No.: US 2024/0408822 A1
(43) Pub. Date: Dec. 12, 2024

(54) METHOD AND DEVICE FOR A LITHOGRAPHY-BASED GENERATIVE MANUFACTURE OF A THREE-DIMENSIONAL COMPONENT

(71) Applicant: UPNANO GMBH, Wien (AT)

(72) Inventor: Peter GRUBER, Wien (AT)

(73) Assignee: UPNANO GMBH, Wien (AT)

(21) Appl. No.: 18/697,821

(22) PCT Filed: Sep. 28, 2022
(86) PCT No.: PCT/IB2022/059236

§ 371 Date: Apr. 2, 2024

(30) Foreign Application Priority Data
Oct. 6, 2021 (EP) 21020496.2

(51) Int. Cl. B29C 64/286; B29C 64/135; B29C 64/268; B29C 64/393; B33Y 30/00; G03F 7/00

(52) U.S. Cl. CPC B29C 64/286; B29C 64/135; B29C 64/268; B29C 64/393; B33Y 30/00; G03F 7/70416

(57) ABSTRACT

In a method for a lithography-based generative manufacture of a three-dimensional component, a beam is split into a plurality of beams by a beam splitter, said beams being focused onto focal points within a material by means of an optical imaging unit, wherein the focal points are adjusted by means of a deflecting unit which is arranged upstream of the optical imaging unit in the beam direction, whereby a volume element of the material is solidified by means of multi-photon absorption at the focal point of each beam one after the other, and a number of acousto-optical modulator modules, said number corresponding to the number of beams, is provided such that an acousto-optical modulator module is arranged in the beam path of each beam.

### CROSS-REFERENCE TO RELATED APPLICATIONS

The present application is a national phase application of PCT Application No. PCT/IB2022/059236, filed Sep. 28, 2022, entitled “METHOD AND DEVICE FOR A LITHOGRAPHY-BASED GENERATIVE MANUFACTURE OF A THREE-DIMENSIONAL COMPONENT”, which claims the benefit of European Patent Application No. 21020496.2, filed Oct. 6, 2021, each of which is incorporated by reference in its entirety.

### BACKGROUND OF THE INVENTION

### 1. Field of the Invention

The invention relates to a method for the lithography-based generative production of a three-dimensional component, in which a beam emitted by an electromagnetic radiation source is focused onto a focal point within a material by means of an optical imaging unit and the focal point is displaced by means of a deflection unit arranged upstream of the optical imaging unit in the beam direction, as a result of which a volume element of the material located at the focal point is each successively solidified by means of multiphoton absorption.

### 2. Description of the Related Art

The invention further relates to an apparatus for lithography-based generative manufacturing of a three-dimensional component.

A method for forming a component in which the solidification of a photosensitive material is carried out by means of multiphoton absorption is known, for example, from DE 10111422 A1. For this purpose, a focused laser beam is irradiated into the bath of the photosensitive material, whereby the irradiation conditions for a multiphoton absorption process triggering the solidification are only fulfilled in the immediate vicinity of the focus, so that the focus of the beam is guided to the points to be solidified within the bath volume according to the geometric data of the component to be produced.

A volume element of the material is solidified at the respective focal point, whereby neighboring volume elements adhere to each other and the component is built up by successive solidification of neighboring volume elements. The component can be built up in layers, i.e. the volume elements of a first layer are solidified first before the volume elements of the next layer are solidified.

Irradiation devices for multiphoton absorption methods include an optical system for focusing a laser beam and a deflection device for deflecting the laser beam. The deflection device is designed to focus the beam successively on focal points within the material that lie in one and the same plane, preferably perpendicular to the direction of beam incidence into the material. In an x,y,z coordinate system, this plane is also called the x,y plane. The solidified volume elements created by the beam deflection in the x,y plane form a layer of the component.

To build up the next layer, the relative position of the focusing optics relative to the component is changed in the z-direction, which corresponds to the direction of incidence of the at least one beam into the material and is perpendicular to the x,y-plane. By adjusting the focusing optics relative to the component, which is usually motorized, the focal point is shifted to a new x,y plane, which is spaced from the previous x,y plane in the z direction by the desired layer thickness.

Structuring a suitable material using multiphoton absorption offers the advantage of exceedingly high structure resolution, with volume elements with minimum structure sizes of up to 50 nm×50 nm×50 nm being achievable. However, due to the small focal point volume, the throughput of such a method is very low, since, for example, for a volume of 1 mm³, a total of more than 10⁹ points must be irradiated. This leads to very long construction times, which is the main reason for the low industrial use of multiphoton absorption processes.

In order to increase the component throughput without losing the possibility of a high structural resolution, it has already been proposed to vary the volume of the focal point at least once during the construction of the component, so that the component is constructed from solidified volume elements of different volumes. Due to the variable volume of the focal point, high resolutions are possible (with a small focal point volume). At the same time, a high writing speed (measured in mm³/h) is achievable (with a large focal point volume). Thus, by varying the focal point volume, high resolution can be combined with high throughput. The variation of the focal point volume can be used, for example, in such a way that a large focal point volume is used in the interior of the component to be built up in order to increase the throughput, and a smaller focal point volume is used on the surface of the component in order to form the component surface with high resolution. Increasing the focal point volume allows for higher structuring throughput, since the volume of material solidified in one irradiation instance is increased. To maintain high resolution at high throughput, small focal point volumes can be used for finer structures and surfaces, and larger focal point volumes can be used for coarse structures and/or to fill interior spaces. Methods and devices for changing the focal point volume are described in WO 2018/006108 A1.

### SUMMARY OF THE INVENTION

The invention aims to further develop a method and a device for the lithography-based generative production of a three-dimensional component in such a way that the writing speed (measured in mm³/h) is increased even further.

To solve this problem, the invention provides in a method of the type mentioned above that the beam is split into a plurality of beams by a beam splitter, each of which is successively focused onto focal points within the material by means of the deflection unit and the optical imaging unit, a number of acousto-optic modulator modules corresponding to the number of beams being provided, so that an acousto-optic modulator module which diffracts the beam is arranged in the beam path of each beam.

The invention thus enables parallel writing with a plurality of beams, so that the writing speed is multiplied accordingly by the number of beams. The beam splitter is designed to split the beam into at least two beams. The beam splitter is preferably designed to split the beam into 2, 4, 8, 16, 32 or 64 beams. Any other number of beams is also possible, e.g. an odd number of beams.

Because an acousto-optic modulator module is arranged in the beam path of each beam, each beam can be influenced independently of the other beams, preferably in such a way that the position of the focal point of the respective beam can be adjusted independently of the focal points of the other beams or that the radiation intensity of the respective beam can be adjusted independently of the focal points of the other beams.

Depending on the configuration of the acousto-optic modulator modules, the focal point can be displaced in any spatial direction. Preferably, at least one of the acousto-optic modulator modules is controlled in order to shift the focal point of the associated beam in a z-direction, whereby the z-direction corresponds to a direction of incidence of the respective beam into the material.

Alternatively or additionally, at least one of the acousto-optic modulator modules can be controlled in order to shift the focal point of the associated beam in an x and/or y direction, the x and y directions corresponding to two orthogonal directions in a plane perpendicular to the direction of incidence of the respective beam.

By arranging at least one acousto-optic modulator in the beam path of each beam, each focal point can be shifted continuously and at high speed in the x, y and/or z direction. This makes it possible to freely select the position of a volume element and therefore also to arrange volume elements outside the z-positions defined by the layer plane in order to achieve optimum adaptation to the surface shape to be achieved in each case. The shifting of the focal point in the x, y and/or z direction does not require any mechanical adjustment of the optical imaging unit relative to the component and is therefore independent of the change from a first to a next layer. In particular, the focal point can be shifted without moving parts, but solely due to the effect of the aforementioned acousto-optic modulator module.

An acousto-optic modulator is an optical component that influences the frequency and direction of propagation or intensity of incident light. For this purpose, an optical grating is created in a transparent solid using sound waves, at which the light beam is diffracted. This can be used in structures known as acousto-optic deflectors to generate beam deflection, whereby the deflection angle depends on the relative wavelengths of light and sound waves in the transparent solid. The deflection angle can be adjusted by changing the sound wave frequency. This can be used for the fine adjustment of the focal point in the x and/or y direction described above.

The displacement in the z-direction is achieved, for example, by generating a sound wave in the acousto-optical deflector, the frequency of which is periodically modulated. By periodically varying the frequency of the sound wave generated in the transparent solid, a so-called “cylindrical lens effect” is formed in an acousto-optical deflector, which focuses the incident light beam in the same way as a cylindrical lens. Specific control of the periodic frequency modulation allows the focal length of the cylindrical lens and thus the divergence of the beam emerging from the acousto-optic deflector to be changed. The beam with the divergence set in this way is guided through an imaging unit of the irradiation device, in which the beam is irradiated into the material in a focused manner by means of a lens. The focal point of the beam introduced into the material varies here in the z-direction as a function of the divergence.

A preferred design here provides that the frequency modulation of the sound wave has a constant sound wave frequency gradient. This favors the creation of the so-called “cylindrical lens effect”.

Preferably, it is further provided that the focal point is displaced by a change in the (constant) sound wave frequency gradient of the frequency modulation. The change of the sound wave frequency gradient can be achieved, for example, by changing the bandwidth of the frequency modulation while keeping the period duration of the periodic modulation constant. Alternatively, the bandwidth can be kept constant and the change of the sound wave frequency gradient can be caused by a change of the period duration.

The fundamental frequency of the sound wave is preferably 50 MHz or more for a transparent solid made of e.g. TeO₂, in particular >100 MHz, especially 100-150 MHz. For example, the fundamental frequency is modulated by at least ±10%, preferably ±20-30%. In the case of a fundamental frequency of, for example, 110 MHz, this is periodically modulated by ±25 MHz, i.e. the bandwidth of the frequency modulation is 50 MHz and the frequency of the sound wave is therefore periodically modulated between 85 MHz and 135 MHz. As already mentioned, the change of the sound wave frequency gradient determines the focal length of the cylindrical lens, whereby the modulation frequency is preferably at least 100 kHz, in particular 0.1-10 MHz.

Furthermore, an acousto-optic modulator module can also be used to change the intensity of the beam introduced into the material. The change can also involve reducing the radiation intensity to zero so that the beams coming out of the beam splitter can be switched on and off individually as required. To adjust the radiation intensity, the amplitude of the sound wave introduced into the acousto-optic modulator is changed.

An acousto-optic modulator module comprises at least one acousto-optic modulator, such as one, two or four acousto-optic modulators. In the case of at least two acousto-optic modulators, each modulator can be designed as a separate component through which the respective beam passes in succession. Alternatively, at least two acousto-optic modulators can be functionally combined in a single modulator component (so-called multichannel design), which has a crystal with corresponding sound input for each channel.

Preferably, at least two acousto-optic modulators arranged one behind the other in the beam path are used in the acousto-optic modulator modules, with the at least two acousto-optic modulators preferably having a direction of beam deflection that is essentially perpendicular to one another or the same orientation of beam deflection. The combination of two acousto-optic modulators, preferably arranged directly behind each other and perpendicular to each other, eliminates the astigmatism that would otherwise occur with a single modulator. If two acousto-optic modulators are arranged in one plane, the possible adjustment path of the focal point in the x and y directions is doubled. According to a further preferred embodiment, four acousto-optic modulators arranged in series can be provided, of which the first two modulators form a first pair and the following two modulators form a second pair. The modulators within a pair are each designed with the same orientation of beam deflection and the modulators of the first pair have a direction of beam deflection that is perpendicular to the modulators of the second pair.

While the shifting of the focal points by the acousto-optical modulator modules is used for fine positioning of the focal points, e.g. to solidify volume elements outside the usual grid points (so-called “grayscale lithography”), the writing beams are moved through the entire writing area in the x and y directions by means of a deflection unit separate from the acousto-optical modulator modules. In this context, a preferred design provides for the beams to be subjected to a joint deflection in the x and y directions by means of the deflection unit downstream of the acousto-optical modulator modules in the beam path, in particular a galvanometer scanner. The deflection unit is advantageously arranged in the beam path between the acousto-optic modulator modules and the optical imaging unit. For two-dimensional beam deflection, either a mirror can be deflected in two directions or two orthogonally pivotable mirrors can be set up close to each other, by which the beam is reflected. It is also possible to arrange a lens system, in particular a 4f arrangement, between the mirrors so that the axis of rotation of the first mirror is projected onto the second mirror, thereby avoiding geometric imaging errors. The two mirrors can each be driven by a galvanometer drive or electric motor. In any case, it is essential that all beams that are generated by the beam splitter and then each pass through an acousto-optical modulator module are deflected with the aid of one and the same deflection unit and then focused into the material with one and the same optical imaging unit.

Preferably, the component is built up layer by layer with layers extending in the x-y plane, whereby the change from one layer to the next layer involves changing the relative position of the optical imaging unit relative to the component in the z direction. The mechanical adjustment of the relative position of the optical imaging unit relative to the component results in the coarse adjustment of the focal points in the z-direction, namely the change from one layer to the next. For the adjustment of intermediate stages in the z-direction, i.e. for the fine positioning of the focal point in the z-direction, the position of the focal points is changed by means of the aforementioned acousto-optic modulator modules.

Preferably, the focal point can be shifted in the z-direction by means of the acousto-optic modulator modules within the layer thickness of a layer. Several sub-layers of volume elements arranged one above the other in the z-direction can also be produced within one layer without having to mechanically adjust the relative position of the optical imaging unit relative to the component.

According to a preferred application of the invention, at least one of the focal points is displaced in the z-direction by means of the acousto-optic modulator modules in order to form a curved outer contour of the component. Alternatively or additionally, at least one of the focal points can be displaced in the z-direction by means of the acousto-optic modulator module in order to form an outer contour of the component that is inclined relative to the x,y-plane. The displacement of at least one of the focal points in the z-direction can follow the surface shape by positioning the focal point in the edge area of the component at a distance from the surface of the component to be produced that corresponds to the distance of the imaginary center of the volume element to be solidified from the outer surface of the volume element.

According to a preferred method the material is present on a material carrier, such as in a trough, and the irradiation of the material is carried out from below through the material carrier, which is permeable to the radiation at least in some areas. In this case, a build platform can be positioned at a distance from the material carrier and the component can be built up on the build platform by solidifying material located between the build platform and the material carrier. Alternatively, it is also possible to irradiate the material from above.

In the context of the present invention, the construction time can be considerably reduced if the layers located in the interior of the component are built up with a high layer thickness and therefore with volume elements having a large volume and the edge areas are built up from volume elements having a smaller volume and, in the edge areas, the position of the volume elements is additionally individually adjusted along the z-direction in order to obtain a high structural resolution at the surface.

In a preferred method, the variation of the focal volume is such that the volume ratio between the largest focal point volume during the production of a component and the smallest focal point volume is at least 2, preferably at least 5. Preferably, it is provided that the change of the focal point volume takes place in at least one, preferably two, in particular three, spatial directions perpendicular to each other.

The change in the focal point volume is preferably caused by the deflection of the individual beams by the associated acousto-optic modulator module in a direction transverse to the direction of travel of the respective writing beam, which is caused by the deflection unit, in particular the galvanometer scanner. If the galvanometer scanner moves the respective beam in the x-direction, for example, in order to solidify volume elements lying one behind the other in the x-direction, the associated acousto-optical modulator module can be controlled in such a way that the beam is moved back and forth at high speed transversely to it, e.g. in the y-direction. The amplitude of the aforementioned back and forth movement determines the extent of the volume element. By changing the amplitude, the focal point volume or the volume of the volume element to be solidified can be varied. The back and forth movement takes place at a speed that corresponds to at least 5 times, preferably at least 10 times, the speed in the direction of travel of the writing beam, which is caused by the deflection unit, in particular the galvanometer scanner, in the x-direction. It is understood that the method just described for changing the volume of the volume element to be solidified can be carried out with the x and y directions reversed, so that the deflection unit moves the writing beam or the focal point further in the y direction and the rapid back and forth movement by the acousto-optic modulator module is transverse to it, e.g. in the x direction.

The principle of multiphoton absorption is used in the context of the invention to initiate a photochemical process in the photosensitive material bath. Multiphoton absorption methods include, for example, 2-photon absorption methods. As a result of the photochemical reaction, there is a change in the material to at least one other state, typically resulting in photopolymerization. The principle of multiphoton absorption is based on the fact that the aforementioned photochemical process takes place only in those areas of the beam path where there is sufficient photon density for multiphoton absorption. The highest photon density occurs at the focal point of the optical imaging system, so multiphoton absorption is sufficiently likely to occur only at the focal point. Outside the focal point, the photon density is lower, so the probability of multiphoton absorption outside the focal point is too low to cause an irreversible change in the material by a photochemical reaction. The electromagnetic radiation can pass through the material largely unhindered in the wavelength used, and only at the focal point does an interaction occur between photosensitive material and electromagnetic radiation. The principle of multiphoton absorption is described, for example, in Zipfel et al, “Nonlinear magic: multiphoton microscopy in the biosciences,” NATURE BIOTECHNOLOGY VOLUME 21 NUMBER 11 Nov. 2003.

The source of the electromagnetic radiation may preferably be a collimated laser beam. The laser can emit one or more, fixed or variable wavelengths. In particular, it is a continuous or pulsed laser with pulse lengths in the nanosecond, picosecond or femtosecond range. A pulsed femtosecond laser offers the advantage that a lower average power is required for multiphoton absorption.

Photosensitive material is defined as any material that is flowable or solid under building conditions and that changes to a second state by multiphoton absorption in the focal point volume—for example, by polymerization. The material change must be limited to the focal point volume and its immediate surroundings. The change in substance properties may be permanent and consist, for example, in a change from a liquid to a solid state, but it may also be temporary. Incidentally, a permanent change can also be reversible or non-reversible. The change in material properties does not necessarily have to be a complete transition from one state to the other, but can also be present as a mixed form of both states.

The power of the electromagnetic radiation and the exposure time influence the quality of the produced component. By adjusting the radiation power and/or the exposure time, the volume of the focal point can be varied within a narrow range. If the radiation power is too high, additional processes occur that can lead to damage of the component. If the radiation power is too low, no permanent material property change can occur. For each photosensitive material, there are therefore typical construction process parameters that are associated with good component properties. In the context of the invention, a component is preferably manufactured with a constant radiation power over the entire construction process.

According to a second aspect of the invention, an apparatus is provided for the lithography-based generative production of a three-dimensional component, in particular for carrying out a method according to the first aspect of the invention, comprising a material carrier for a solidifiable material and an irradiation device which can be controlled for the position-selective irradiation of the solidifiable material with at least one beam, characterized in that the irradiation device comprises a beam splitter for splitting an input beam into a plurality of beams, a deflection unit arranged downstream of the beam splitter in the beam path and an optical imaging unit arranged downstream of the deflection unit in order to focus each beam successively onto focal points within the material, as a result of which in each case a volume element of the material located at the focal point can be solidified by means of multiphoton absorption, a number of acousto-optic modulator modules corresponding to the number of beams being provided, so that an acousto-optic modulator module which comprises at least one acousto-optic modulator is arranged in the beam path of each beam.

Preferably, the acousto-optic modulator modules are designed to shift the respective focal point in a z-direction, whereby the z-direction corresponds to a direction of incidence of the associated beam into the material.

Preferably, the control of the at least one acousto-optic modulator module comprises a frequency generator which is designed for periodic modulation of the sound wave frequency.

Preferably, it is provided here that the frequency generator is designed to change the sound wave frequency gradient.

It is also preferable that the acousto-optic modulator modules are designed to shift the respective focal point in an x and/or y direction, with the x and y directions corresponding to two orthogonal directions in a plane perpendicular to the direction of incidence of the respective beam.

As already mentioned in connection with the method according to the invention, it is advantageous if the acousto-optic modulator modules each comprise at least two acousto-optic modulators arranged one behind the other in the beam path, the at least two acousto-optic modulators preferably having a direction of their beam deflection that is essentially perpendicular to one another or an identical orientation of their beam deflection

Furthermore, the deflection unit can be arranged downstream of the acousto-optical modulator modules in the beam path, in particular formed by a galvanometer scanner, which is designed to effect a joint displacement of the focal points in an x-y plane running transverse to the z direction.

In particular, the irradiation device can be designed to build up the component layer by layer with layers extending in the x-y plane, with the change from one layer to the next layer comprising the change in the relative position of the optical imaging unit relative to the component in the z direction.

The irradiation device is preferably designed in such a way that the fine adjustment of the focal point in the z-direction takes place within the layer thickness of a layer by means of the acousto-optical modulator.

Furthermore, it can be provided that the material is present on a material carrier, such as in a trough, and the irradiation of the material is carried out from below through the material carrier, which is permeable to the radiation at least in certain areas.

The build platform is preferably positioned at a distance from the material carrier and the component is built up on the build platform by solidifying volume elements located between the build platform and the material carrier.

It is advantageous if the volume of the focal point is varied at least once during the construction of the component, so that the component is constructed from solidified volume elements of different volumes.

The imaging unit can be designed as an f-theta lens or preferably consists of a microscopy objective and relay optics in a 4f arrangement, whereby the deflection unit and the objective are located in the focal plane of the corresponding lenses.

### BRIEF DESCRIPTION OF THE DRAWINGS

The invention is explained in more detail below with reference to schematic examples of embodiments shown in the drawing. In this

FIG. 1 shows a schematic representation of a device according to the invention,

FIGS. 2, 3 and 4 a detailed view of alternative designs of an acousto-optic modulator module and

FIG. 5 a schematic representation of the focal points in the image field of the device during the production of a component.

### DETAILED DESCRIPTION

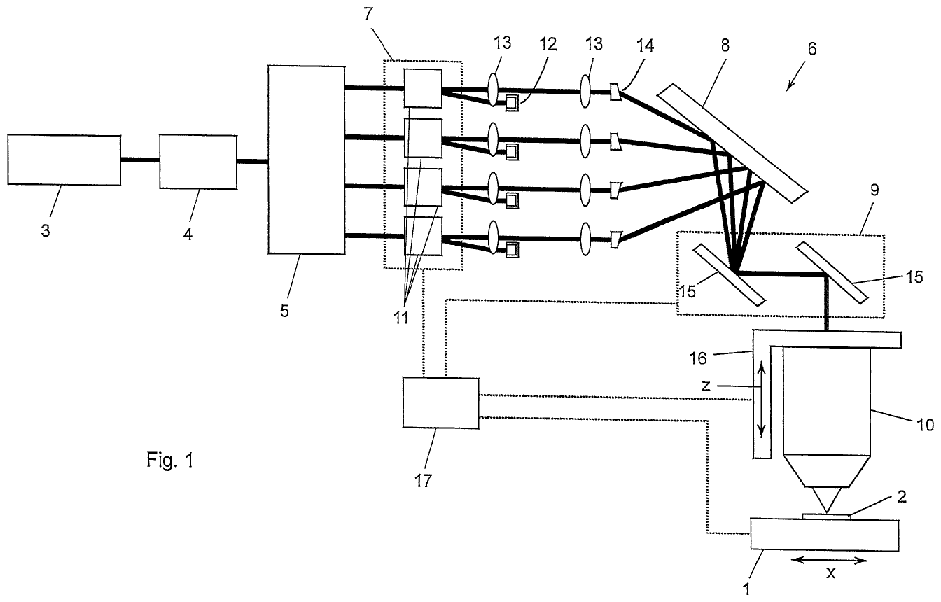

In FIG. 1, a carrier is labeled 1 on which a component is to be mounted. The carrier is coated with a photopolymerizable material 2 into which laser beams are focused, each laser beam being focused successively on focal points within the photopolymerizable material, whereby a volume element of the material located at the focal point is solidified by means of multiphoton absorption. For this purpose, a laser beam is emitted from a radiation source 3, passed through a pulse compressor 4 and split into a plurality of beams (in this case four beams) in a beam splitter 5. The rays are now irradiated into the material 2 by means of an irradiation device 6. For this purpose, the irradiation device 6 comprises an acousto-optical modulator unit 7, a deflecting mirror 8, a galvanometer scanner 9 and an optical imaging unit 10 comprising an objective which introduces the laser beams into the material 2 within a writing range.

The acousto-optic modulator unit 7 comprises a number of acousto-optic modulator modules 11 corresponding to the number of beams, of which at least one acousto-optic modulator splits the respective beam into a zero-order beam and a first-order beam. The zero-order beam is collected in a beam trap 12. The first-order beam is directed via relay lenses 13 and a deflector 14 onto the deflecting mirror 8, which guides the beams into the deflection unit 9 (e.g. a galvanometer scanner), in which the beams are successively reflected by two mirrors 15. The mirrors 15 are driven to swivel about axes of rotation that are orthogonal to each other so that the beams can be deflected in both the x and y directions. The two mirrors 15 can each be driven by a galvanometer drive or electric motor. The beams emerging from the deflection unit 9 preferably enter the lens 10 via an optional relay lens system (not shown), which focuses the beams into the photopolymerizable material as already mentioned.

To build up the component layer by layer, volume elements of one layer after the other are solidified in the material. To build up a first layer, the laser beams are focused one after the other on focal points arranged in the focal plane of the lens 10 within the material 2. The joint deflection of the beams in the x,y plane is carried out with the aid of the deflection unit 9, whereby the writing range is limited by the lens 10. To change to the next plane, the lens 10 attached to a carrier 16 is moved in the z-direction relative to the carrier 1 by the distance between the layers, which corresponds to the layer thickness. Alternatively, the carrier 1 can also be adjusted relative to the fixed lens 10.

If the component to be produced is larger in the x and/or y direction than the writing range of the lens 10, substructures of the component are built up next to each other (so-called stitching). For this purpose, the carrier 1 is arranged on a cross table, which can be moved in the x and/or y direction relative to the irradiation device 6.

A control unit 17 is also provided, which controls the acousto-optical modulator unit 7, the deflection unit 9, the height adjuster 16 and the carrier 1 attached to the cross table.

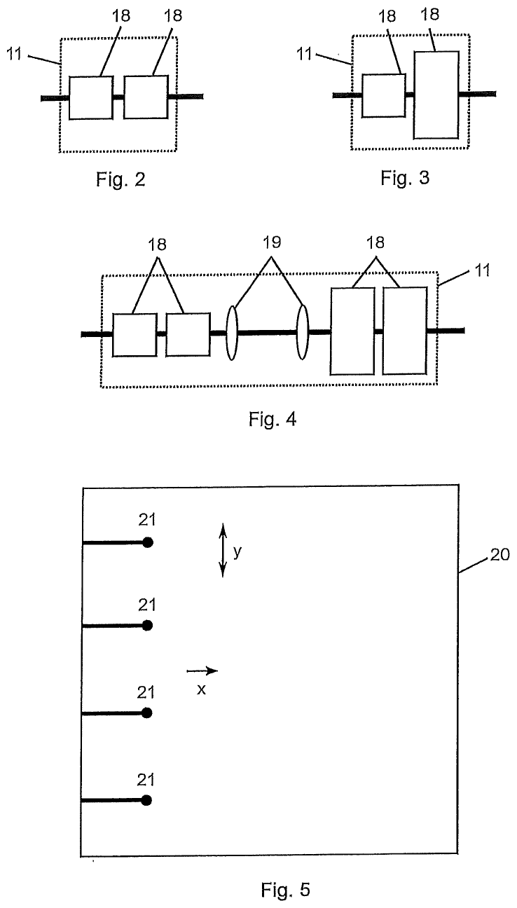

As shown in FIG. 2, an acousto-optic modulator module 11 can have two acousto-optic modulators 18 arranged one after the other, whose direction of beam deflection coincides. This has the effect that the deflection is twice as large compared to a single acousto-optic modulator, and that the deflection in the x, y and z directions can be controlled independently of each other. This means that any point within the available deflection range can be controlled and fine adjustment of the focal point in the z-direction is possible. The disadvantage of this arrangement is the astigmatism caused by the cylindrical lens effect of the acousto-optic modulator.

The acousto-optical modulators 11 each form a cylindrical lens effect that depends on the sound wave frequency gradient of the frequency modulation. The equivalent focal length of the cylindrical lens Fₗ can be calculated as follows:

$${F}_{l} = \frac{{v}_{a}^{2}}{λ \frac{{dF}_{a}}{dt}}$$

where v_{α} is the acoustic propagation velocity in the crystal, λ is the wavelength of the laser beam, and dF_{α/dt} is the acoustic wave frequency gradient in the crystal. In TeO₂ with a propagation speed of 4200 m/s at a laser wavelength of 780 nm and traversing a bandwidth of ±25 MHz (e.g., starting from a fundamental excitation frequency of 110 MHz) within 0.2 μs, the focal length of the acousto-optic cylindrical lens is 90 mm. For an objective 4 with a focal length of 9 mm and a 20× expansion, this results in a new focal length of the entire system of

$${F}_{t o t a l} = \frac{{F}_{Obj} {F}_{l}}{{F}_{Obj} + {F}_{l}}$$

which corresponds to a displacement in the z-direction, depending on the sign of the gradient, of ±90 μm for the parameters mentioned above. By changing the sound wave frequency gradient, the z-position of the volume element can be adjusted linearly and steplessly.

In the alternative embodiment according to FIG. 3, an acousto-optic modulator module 11 comprises two acousto-optic modulators 18 arranged one after the other, the direction of beam deflection of which is perpendicular to one another. With regard to the deflected first-order beam, this acousto-optic modulator module 11 acts as a cylindrical lens with an adjustable focal length, so that the first-order beam has an adjustable divergence, which allows the focal point to be adjusted in the x and y directions, whereby the deflection direction of the deflection unit can be freely selected. Furthermore, this arrangement minimizes the resulting astigmatism, as two mutually orthogonal cylindrical lenses are produced.

FIG. 4 shows a modified embodiment of the acousto-optic modulator module 11, which has a first pair of acousto-optic modulators 18 and a second pair of acousto-optic modulators 18, between which relay lenses 19 are arranged to ensure that the focal point at the input and output of the acousto-optic modulator module 11 are arranged on the same line. The two acousto-optic modulators 18 of each pair have the same deflection direction. The direction of deflection of the modulators of the first pair is perpendicular to the direction of deflection of the modulators of the second pair. This has the effect of combining the advantages of the design shown in FIG. 2 with those of the design shown in FIG. 3.

In FIG. 5, the writing range or image field 20 of the optical imaging unit 10 is shown in the x and y directions, whereby this is the section of the component that can be built up between the optical imaging unit 10 and the component to be built up without changing the relative position in the x and y directions. Four focal points 21 can be seen, which are spaced apart so that four volume elements of the component can be produced independently of each other at the same time. The joint movement of the focal points 21 in the x-direction takes place with the aid of the deflection unit 9. The focal points 21 can also be finely adjusted independently of each other in the x, y and/or z direction by means of the respective acousto-optic modulator module 11, starting from their current basic position defined by the deflection unit 9. For example, during the movement of the focal points in the x-direction caused by the deflection unit 9, a fine adjustment can be made in the z-direction in order to adapt the position of volume elements to a curved or inclined component contour relative to the coordinate directions, similar to “grayscale lithography”. Furthermore, during the movement of the focal points in the x-direction caused by the deflection unit 9, a fine adjustment can be made in the y-direction in such a way that the laser beam is moved back and forth at high speed in order to be able to adjust the expansion of the volume element to be solidified in the y-direction depending on the amplitude of the back and forth movement.

1-17. (canceled)

18. A method for the lithography-based generative production of a three-dimensional component, comprising:
focusing a beam emitted by an electromagnetic radiation source by an optical imaging unit onto a focal point within a material; and
displacing the focal point by a deflection unit arranged upstream of the optical imaging unit in the beam direction;
wherein a volume element of the material located at the focal point is each successively solidified by multiphoton absorption;
wherein the beam is divided by a beam splitter into a plurality of beams, each of which is successively focused on focal points within the material by the deflection unit and the optical imaging unit; and
wherein a number of acousto-optic modulator modules corresponding to the number of beams are provided, so that an acousto-optic modulator module which diffracts the beam is arranged in the beam path of each beam.

19. The method according to claim 18, wherein at least one of the acousto-optic modulator modules is controlled in order to shift the focal point of the associated beam in a z-direction, the z-direction corresponding to a direction of incidence of the respective beam into the material.

20. The method according to claim 18, wherein at least one of the acousto-optic modulator modules is controlled in order to displace the focal point of the associated beam in an x and/or y direction, the x and y directions corresponding to two orthogonal directions in a plane perpendicular to the direction of incidence of the respective beam.

21. The method according to claim 18, wherein at least two acousto-optic modulators arranged one behind the other in the beam path are used in each of the acousto-optic modulator modules.

22. The method according to claim 21, wherein the at least two acousto-optic modulators have a direction of a beam deflection substantially perpendicular to one another or an identical orientation of the beam deflection

[symbol]

23. The method according to claim 18, wherein the beams are subjected to a joint deflection in the x and y directions by the deflection unit arranged downstream of the acousto-optical modulator modules in the beam path.

24. The method according to claim 23, wherein the deflection unit comprises a galvanometer scanner.

25. The method according to claim 18, wherein the component is built up layer by layer with layers extending in the x-y plane, the change from one layer to a next layer comprising the change in the relative position of the optical imaging unit relative to the component in the z direction.

26. The method according to claim 25, wherein the focal point is displaced in the z-direction by means of the acousto-optic modulator modules within a layer thickness of a layer.

27. The method according to claim 18, wherein at least one of the focal points is displaced in the z-direction by means of the acousto-optic modulator modules in order to form a curved outer contour or an outer contour of the component which runs obliquely relative to the x,y-plane.

28. A device for the lithography-based generative production of a three-dimensional component, comprising:
a material carrier for a solidifiable material; and
an irradiation device controllable for a position-selective irradiation of the solidifiable material with at least one beam;
wherein the irradiation device comprises a beam splitter for splitting an input beam into a plurality of beams, a deflection unit arranged downstream of the beam splitter in the beam path, and an optical imaging unit arranged downstream of the deflection unit in order to focus each beam successively on focal points within the material;
wherein a respective volume element of the material located at the focal point can be solidified by means of multiphoton absorption; and
wherein a number of acousto-optic modulator modules corresponding to the number of beams is provided, so that an acousto-optic modulator module comprising at least one acousto-optic modulator is arranged in the beam path of each beam.

29. The device according to claim 28, wherein the acousto-optical modulator modules are designed to displace the respective focal point in a z-direction, the z-direction corresponding to a direction of incidence of the associated beam into the material.

30. The device according to claim 28, wherein the at least one acousto-optic modulator comprises a frequency generator configured for periodic modulation of the sound wave frequency.

31. The device according to claim 30, wherein the frequency generator is configured to change the sound wave frequency gradient.

32. The device according to claim 28, wherein the acousto-optical modulator modules are configured for displacing the respective focal point in an x- and/or y-direction, the x- and y-directions corresponding to two orthogonal directions in a plane perpendicular to the direction of incidence of the respective beam.

33. The device according to claim 28, wherein the acousto-optic modulator modules each comprise at least two acousto-optic modulators arranged one behind the other in the beam path.

34. The device according to claim 33, wherein the at least two acousto-optic modulators have a direction of a beam deflection substantially perpendicular to one another or an identical orientation of the beam deflection

[symbol]

35. The device according to claim 28, wherein the deflection unit is arranged downstream of the acousto-optical modulator modules in the beam path, which is configured to effect a common displacement of the focal points in an x-y plane extending transversely to the z direction.

36. The device according to claim 28, wherein the irradiation device is configured to build up the component layer by layer with layers extending in the x-y plane, the change from one layer to a next layer comprising the change in the relative position of the optical imaging unit relative to the component in the z direction.

37. The device according to claim 28, wherein the irradiation device is configured so that the displacement of the focal point in the z-direction by the acousto-optic modulator module takes place within a layer thickness of a layer.
